(19) United States
(12) Patent Application Publication
(10) Pub. No.: US 2024/0047459 A1
(43) Pub. Date: Feb. 8, 2024

(54) Integrated Standard Cell with Contact Structure

(71) Applicant: Taiwan Semiconductor Manufacturing Company, Ltd., Hsin-Chu (TW)

(72) Inventors: Yu-Lung Tung, Kaohsiung City (TW); Xiaodong Wang, Hsinchu City (TW); Jhon Jhy Liaw, Hsinchu City (TW)

(21) Appl. No.: 17/879,836

(22) Filed: Aug. 3, 2022

(51) Int. Cl. H01L 27/092; H01L 27/02; H01L 21/8238; H01L 23/528; H01L 29/417

(52) U.S. Cl. CPC H01L 27/092; H01L 27/0207; H01L 21/823871; H01L 23/528; H01L 29/41725

(57) ABSTRACT

An IC structure includes a first standard cell having a first pFET and a first nFET integrated; a first, second and third gates longitudinally oriented along a first direction and configured in the first standard cell; a first gate contact landing on the first gate and being adjacent two S/D contacts on two opposite edges of the first gate; a second gate contact landing on the second gate and being adjacent a single S/D contact on one edge of the second gate; and a third gate contact landing on the third gate and being free from any S/D contact. The first, second and third gate contacts span a first dimension D1, a second dimension D2, and a third dimension D3, respectively, along a second direction being orthogonal to the first direction. D1 is less than D2 and D2 is less than D3.

### BACKGROUND

In the design of integrated circuits (IC), standard cells with certain functions are repeated used with high frequency. Accordingly, those standard cells are predesigned and packed in a cell library. The cell library is provided to the IC designers for their particular designing. During integrated circuit designing, the standard cells are retrieved from the cell libraries and placed into desired locations, thus reducing the design effort. Routing is then performed to connect the standard cells and other circuit blocks to form the desired integrated circuit. Pre-defined design rules are followed when making and placing the standard cells into the desired locations. For example, a standard cell is placed close to another standard cell, the space between those two standard cells is determined according to the pre-defined rules. The reserved space between the standard cells and the cell boundaries results in a significant increase in the areas of the standard cells. In addition, because the active regions are spaced apart from the cell boundaries, when the standard cells are placed abutting each other, the active regions will not be joined, even if some of the active regions in the neighboring cells need to be electrically coupled. The spaced apart active regions have to be electrically connected using metal lines. The performance of the resulting device is degraded. Layout patterns and configurations can affect the yield and the design performance of the standard cells. In another example, an interconnect structure including various contacts and vias are formed on the gate electrodes and active regions. However, if those conductive features are designed with greater dimensions, short issues may occur due to misalignment and processing window. if those conductive features are designed with less dimensions, contact resistances are increased and misalignment may introduce open issues. It is therefore desired to have an integrated circuit layout structure, and the method making the same to address the above issues.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a top view of an integrated circuit (IC) structure constructed according to various aspects of the present disclosure in one embodiment.

FIG. 2A is a top view of an IC structure constructed according to various aspects of the present disclosure in one embodiment.

FIGS. 2B, 2C and 2D are cross-sectional views of the IC structure in FIG. 2A, constructed according to various aspects of the present disclosure in one embodiment.

FIG. 2E is a top view of the IC structure in FIG. 2A, constructed according to various aspects of the present disclosure in one embodiment.

FIGS. 3A, 3B and 3C are sectional views of a gate in an IC structure in accordance with some embodiments.

FIG. 4A is a top view of an IC structure constructed according to various aspects of the present disclosure in one embodiment.

FIG. 4B is a top view of the IC structure in FIG. 4A, constructed according to various aspects of the present disclosure in one embodiment.

FIG. 4C is a top view of an IC structure constructed according to various aspects of the present disclosure in one embodiment.

FIG. 4D is a top view of the IC structure in FIG. 4C, constructed according to various aspects of the present disclosure in one embodiment.

FIGS. 5A and 5B are top views of an IC structure constructed according to various aspects of the present disclosure in one embodiment.

FIGS. 6A, 6B and 6C are cross-sectional views of the IC structure in FIG. 4A, constructed according to various aspects of the present disclosure in one embodiment.

FIG. 7 is a cross-sectional view of the IC structure in FIG. 4A, constructed according to various aspects of the present disclosure in one embodiment.

FIGS. 8A and 8B are tops view of an IC structure constructed according to various aspects of the present disclosure in one embodiment.

### DETAILED DESCRIPTION

The following disclosure provides many different embodiments, or examples, for implementing different features. Reference numerals and/or letters may be repeated in the various examples described herein. This repetition is for the purpose of simplicity and clarity and does not in itself dictate a relationship between the various disclosed embodiments and/or configurations. Further, specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Moreover, the formation of a feature on, connected to, and/or coupled to another feature in the present disclosure may include embodiments in which the features are formed in direct contact, and may also include embodiments in which additional features may be formed interposing the features, such that the features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one feature relationship to another feature. The spatially relative terms are intended to cover different orientations of the device including the features. Still further, when a number or a range of numbers is described with “about,” “approximate,” and the like, the term is intended to encompass numbers that are within a reasonable range including the number described, such as within +/−10% of the number described, or other values as understood by person skilled in the art. For example, the term “about 5 nm” encompasses the dimension range from 4.5 nm to 5.5 nm.

The present disclosure provides various embodiments of integrated circuit (IC) formed on a semiconductor substrate. The integrated circuit has a design layout incorporated with various standard cells. The standard cells are predesigned IC structure to be repeatedly used in individual IC designs. Effective IC design layouts include various predesigned standard cells and predefined rules of placing those standard cells for enhanced circuit performing and reduced circuit areas.

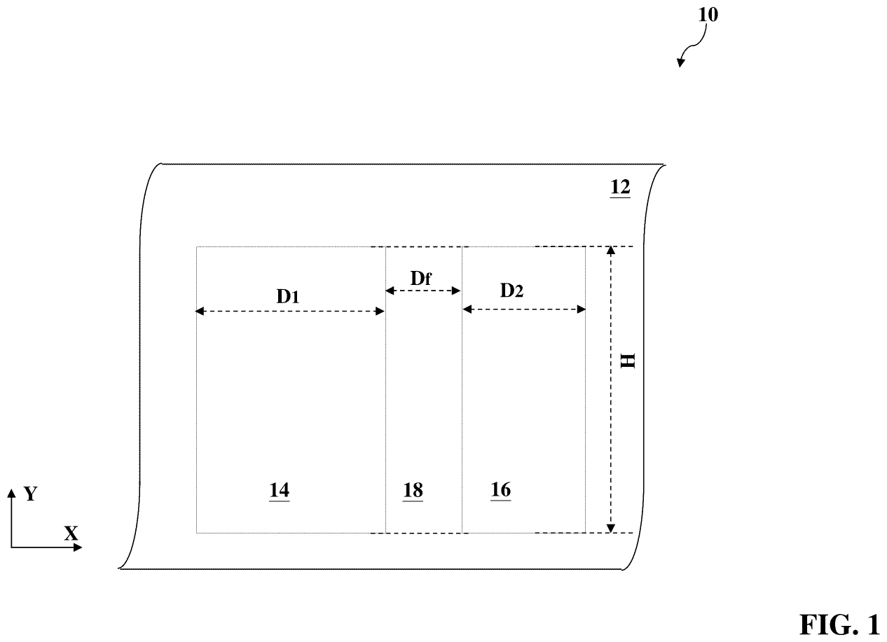

FIG. 1 is a top view of an integrated circuit (IC) structure 10, constructed according to various aspects of the present disclosure in one embodiment. In some embodiments, the IC structure 10 is formed on flat active regions and includes field-effect transistors (FETs). In some embodiments, the IC structure 10 is formed on fin active regions and includes fin field-effect transistors (FinFETs). In yet some embodiments, the IC structure 10 is formed on active regions having multiple channels vertically stacked over, such as gate-all-round field-effect transistors (GAA FETs). With the IC structure 10 as an example for illustration, an IC structure and a method to design, incorporate and fabricate standard cells are collectively described.

In various embodiments, the IC structure 10 includes one or more standard cell placed to the IC layout by predefined rules. Those standard cells are repeatedly used in integrated circuit designs and therefore predesigned according to manufacturing technologies and saved in a standard cell library. IC designers could retrieve those standard cells, incorporate in their IC designs, and place into the IC layout according to the predefined placing rules. The standard cells may include various basic circuit devices, such as inverter, AND, NAND, OR, XOR, and NOR, which are popular in digital circuit design for applications, such as central processing unit (CPU), graphic processing unit (GPU), and system on chip (SOC) chip designs. The Standard cells may include other frequently used circuit blocks, such flip-flop circuit and latch.

The IC structure 10 includes a semiconductor substrate 12. The semiconductor substrate 12 includes silicon. Alternatively, the substrate 12 may include an elementary semiconductor, such as silicon or germanium in a crystalline structure; a compound semiconductor, such as silicon germanium, silicon carbide, gallium arsenic, gallium phosphide, indium phosphide, indium arsenide, and/or indium antimonide; or combinations thereof. Possible substrates 12 also include a silicon-on-insulator (SOI) substrate. SOI substrates are fabricated using separation by implantation of oxygen (SIMOX), wafer bonding, and/or other suitable methods.

The substrate 12 also includes various isolation features, such as isolation features formed on the substrate 12 and defining various active regions on the substrate 12. The isolation feature utilizes isolation technology, such as shallow trench isolation (STI), to define and electrically isolate the various active regions. Each active region is surrounded by a continuous isolation feature such that it is separated from adjacent active regions. The isolation feature includes silicon oxide, silicon nitride, silicon oxynitride, other suitable dielectric materials, or combinations thereof.

The IC structure 10 only illustrate two standard cells 14 and 16 displaced next to each other. The standard cells 14 and 16 may be placed with a common boundary line or alternatively displaced with a distance such that a fill cell 18 is inserted therebetween. The fill cell 18 is configured between standard cells to provide proper separation and isolation. The fill cell 18 includes various features, such as active regions, gate stacks, and etc. However, those features are not configured as components of the integrated circuit but instead placed to provide effective isolation to the standard cells and to enhance the performance of the integrated circuit. The standard cells 14 and 16 may have a same size or alternatively different sizes. In the illustrated embodiment, the standard cells 14 and 16 span dimensions D1 and D2 along Y direction, respectively, and span a same dimension H along X direction. The fill cell 18 spans a dimension Df along X direction.

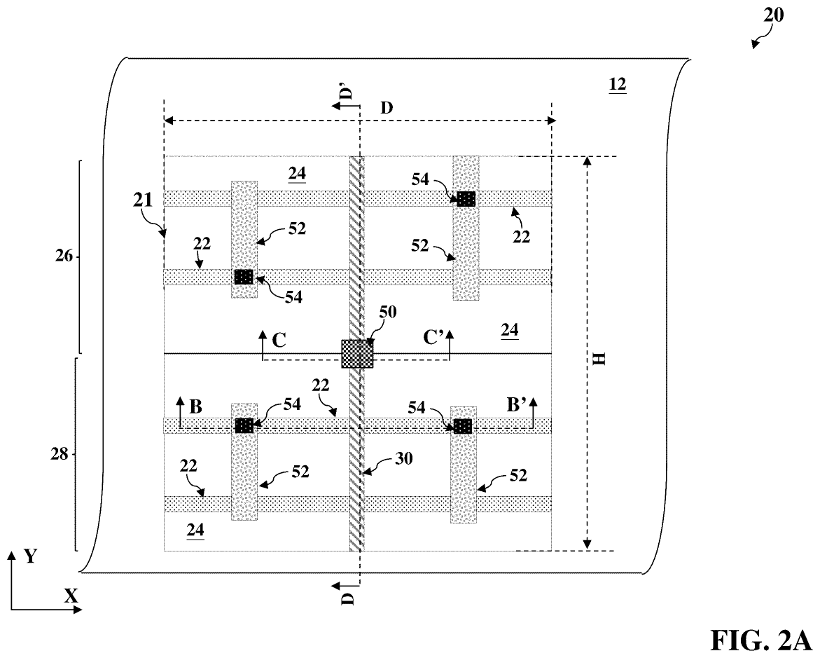

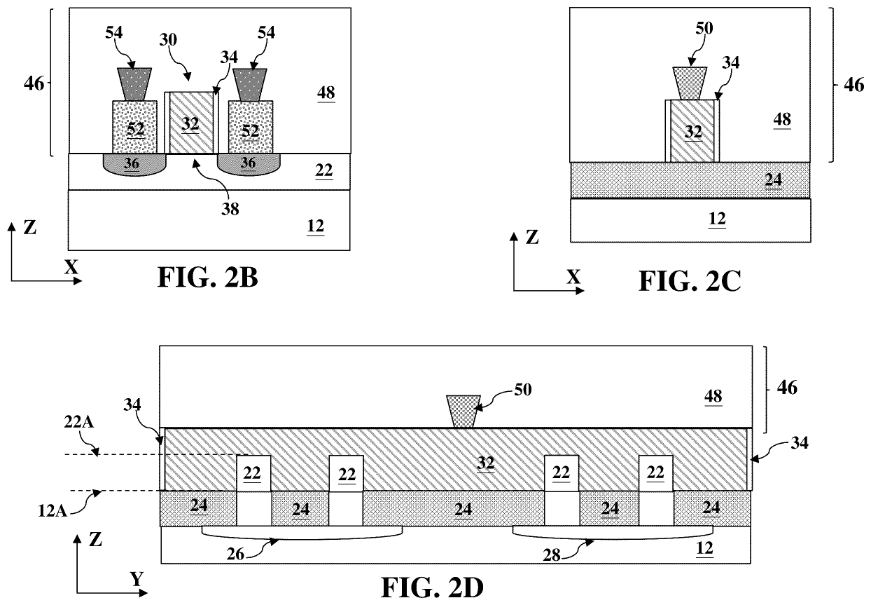

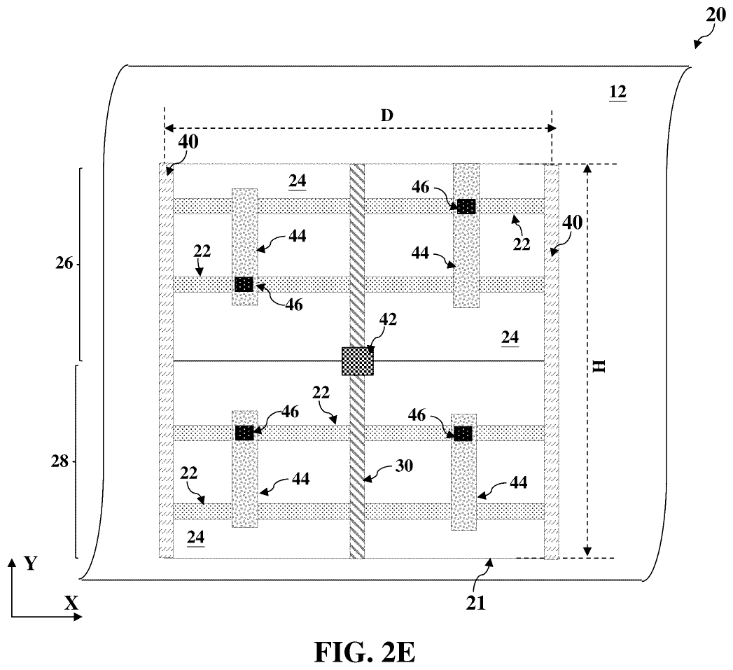

FIG. 2A is a top view a sectional view and of an integrated circuit (IC) structure 20 and FIGS. 2B, 2C and 2D are sectional views of the IC structure 20 along the dashed line BB′, CC′ and DD′, respectively, constructed according to various aspects of the present disclosure in one embodiment. In some embodiments, the IC structure 20 is formed on flat active regions and includes field-effect transistors (FETs). The IC structure 20 only illustrates one standard cell 21, which may be standard cell 14 or 16, for example.

The substrate 12 also includes various isolation features 24 formed on the substrate 12 and defining various active regions 22 on the substrate 12. The isolation features 24 utilize isolation technology, such as shallow trench isolation (STI), to define and electrically isolate various active regions 22. Each active region 22 is surrounded by a continuous isolation feature 24 such that it is separated from other adjacent active regions. The isolation features 24 include silicon oxide, silicon nitride, silicon oxynitride, other suitable dielectric materials, or combinations thereof. The isolation features 24 are formed by any suitable process. As one example, forming STI features includes a lithography process to expose a portion of the substrate, etching a trench in the exposed portion of the substrate (for example, by using a dry etching and/or wet etching), filling the trench by deposition with one or more dielectric materials, and planarizing the substrate and removing excessive portions of the dielectric material(s) by a polishing process, such as a chemical mechanical polishing (CMP) process. In some examples, the STI features 24 may have a multi-layer structure, such as a thermal oxide liner layer and filling layer(s) of silicon nitride or silicon oxide.

An active region 22 is a region with a semiconductor surface wherein various doped features are formed and configured for one or more device, such as a diode, a transistor, and/or other suitable devices. The active region 22 may include a semiconductor material similar to that (such as silicon) of the bulk semiconductor material of the substrate 12 or different semiconductor material, such as silicon germanium (SiGe), silicon carbide (SiC), or multiple semiconductor material layers (such as alternative silicon and silicon germanium layers) formed on the substrate 12 by epitaxial growth, for performance enhancement, such as strain effect to increase carrier mobility.

In the disclosed embodiment, the active regions 22 are three-dimensional, such as a fin active region that is vertically extended above the isolation feature. The fin active region 22 is extruded from the substrate 12 and has a three-dimensional profile for more effective coupling between the channel and the gate electrode of a FET. Particularly, the substrate 12 has a top surface 12a and the fin active region 22 has a top surface 22A that is above the top surface of the substrate 12. The fin active region 22 may be formed by selective etching to recess the isolation features 24, or selective epitaxial growth to grow active regions with a semiconductor material same or different from that of the substrate 12, or a combination thereof. In the disclosed embodiment, a fin active region 22 is longitudinally oriented along X direction.

The semiconductor substrate 12 further includes various doped features, such as n-type doped wells, p-type doped wells, source and drain features, other doped features, or a combination thereof configured to form various devices or components of the devices, such as source and drain features of a field-effect transistor. In the present example illustrated in FIG. 2A, the IC structure 20 includes a negatively doped well (also referred to as N well) 26 and a positively doped well (also referred to as P well) 28, as illustrated in FIG. 2A. The N well 26 includes negative dopant, such as phosphorus. And the P well 28 includes positive dopant, such as boron. The N well 26 and the P well 28 are formed by suitable technologies, such as ion implantation, diffusion or a combination thereof. In the present embodiment, two fin active regions 22 are formed in the N well 26 and other two fin active regions 22 are formed in the P well 28. In some embodiments, each doped well (N well 26 or P well 28) may include more or less fin active regions 22, such as 1, 3, 4 or any suitable number of fin active region(s) 22.

Various IC devices formed on the semiconductor substrate 12. The IC devices includes fin field-effect transistors (FinFETs), diodes, bipolar transistors, imaging sensors, resistors, capacitors, inductors, memory cells, or a combination thereof. In FIG. 2A, exemplary FinFETs are provided only for illustration.

The IC structure 20 further includes various gates 30 having elongated shape longitudinally oriented along Y direction. In the present embodiment, X and Y directions are orthogonal and define a top surface of the semiconductor substrate 12. A gate 30 includes a gate stack 32 that further includes a dielectric layer and a gate electrode. The gate 30 may further include gate spacers 34 disposed on sidewalls of the gate stacks 32 with one or more functions, such as providing isolation between the gate electrode and source/drain (S/D) features 36. The gate spacers 34 include one or more dielectric materials, such as silicon oxide, silicon nitride, other suitable dielectric material or a combination thereof. The gate spacers 34 are formed by a suitable procedure, such as deposition of dielectric material(s) and anisotropic etching, such as plasma etching. The gate stack 32 is a feature of a FET and functions with other features, such as S/D features 36 and a channel 38, wherein the channel is in a portion of the active region directly underlying the gate stack 32; and the S/D features 36 are in the active region and are disposed on two sides of the gate stack 30. As used herein, a source/drain (S/D) feature may refer to a source or a drain of a device. It may also refer to a region that provides a source and/or drain for multiple devices.” It is noted that the gate 30 should not be confused with a logic gate, such a NOR logic gate. The gate stacks 32 will be further described in detail later.

In some embodiments, the IC structure 20 also includes dielectric gates 40 disposed on the semiconductor substrate 12. A dielectric gate 40 is not a gate and does not function as a gate. Instead, the dielectric gate 40 is a dielectric feature that includes one or more dielectric material and function as an isolation feature, in some instances. In some embodiments, the dielectric gates 40 are added to tune the gate density for enhanced fabrication. For example, a CMP process may be applied to the IC structure 20 and can achieve better and improved planarization effect when the gate density is uniform. In the disclosed embodiment, the dielectric gates 40 are formed on the boundary of the standard cell 20, as illustrated in FIG. 2E in a top view.

Each of the dielectric gates 40 also have an elongated shape oriented in the Y direction. The dielectric gates 40 are similar to the gates 30 in term of formation. In some embodiments, the gates 30 and the dielectric gates 40 are collectively formed by a procedure, such as a gate-last process. In furtherance of the embodiments, dummy gates are first formed by deposition and patterning, in which the patterning further includes lithography process and etching. After the formation of source/drain features, the dummy gates are removed by selective etching. Afterward, a subset of the dummy gates is replaced to form gates 30 by depositing a gate dielectric layer and a gate electrode while the rest of the dummy gates are replaced to form dielectric gates 40 by depositing only one or more dielectric material. A CMP process may be followed to remove excessive materials of gates 30 and dielectric gates 40. Furthermore, the dielectric gate 40 is disposed and configured differently and therefore functions differently. In the present embodiment, some dielectric gates 40 are placed on the borders of the standard cells to function as isolation to separate one standard cell to an adjacent standard cell, and some dielectric gates 40 are placed inside the standard cells for one or more considerations, such as isolation between the adjacent FETs and adjusting pattern density. Thus, the dielectric gates 40 provide isolation function between adjacent IC devices and additionally provides pattern density adjustment for improved fabrication, such as etching, deposition and CMP.

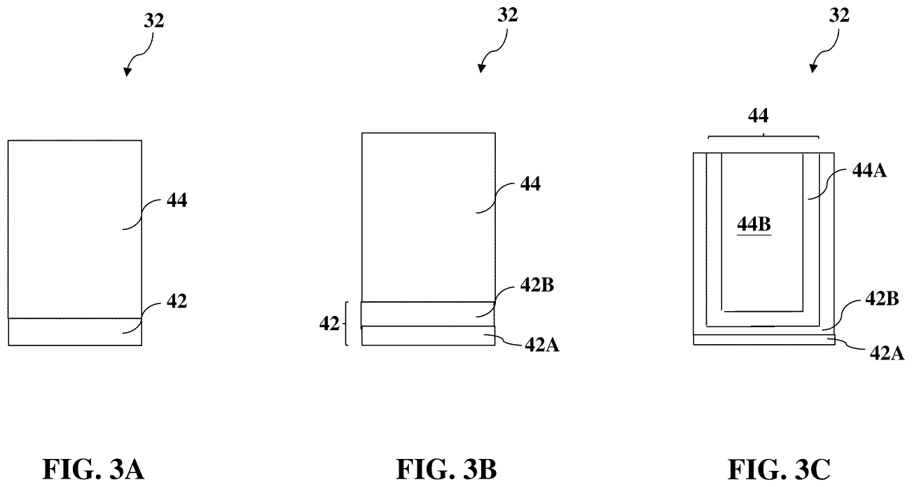

In various embodiments described above, the gate stack 32 is further described with reference to FIGS. 3A-3C in sectional views, according to various embodiments. The gate stack 32 includes a gate dielectric layer 42 (such as silicon oxide) and a gate electrode 44 (such as doped polysilicon) disposed on the gate dielectric layer, as illustrated in FIG. 3A.

In some embodiments, the gate stack 32 alternatively or additionally includes other proper materials for circuit performance and manufacturing integration. For example, the gate dielectric layer 42 includes an interfacial layer 42A (such as silicon oxide) and a high k dielectric material layer 42B, as illustrated in FIG. 3B. The high k dielectric material may include metal oxide, metal nitride or metal oxynitride. In various examples, the high k dielectric material layer includes metal oxide: ZrO2, Al2O3, and HfO2, formed by a suitable method, such as metal organic chemical vapor deposition (MOCVD), physical vapor deposition (PVD), atomic layer deposition (ALD), or molecular beam epitaxy (MBE). In some examples, the interfacial layer includes silicon oxide formed by ALD, thermal oxidation or ultraviolet-Ozone Oxidation. The gate electrode 1204 includes metal, such as aluminum, copper, tungsten, metal silicide, doped polysilicon, other proper conductive material or a combination thereof. The gate electrode may include multiple conductive films designed such as a capping layer, a work function metal layer, a blocking layer and a filling metal layer (such as aluminum or tungsten). The multiple conductive films are designed for work function matching to n-type FET (nFET) and p-type FET (pFET), respectively. In some embodiments, the gate electrode for nFET includes a work function metal with a composition designed with a work function equal 4.2 eV or less and the gate electrode for pFET includes a work function metal with a composition designed with a work function equal 5.2 eV or greater. For examples, the work function metal layer for nFET includes tantalum, titanium aluminum, titanium aluminum nitride or a combination thereof. In other examples, the work function metal layer for pFET includes titanium nitride, tantalum nitride or a combination thereof.

In some embodiments illustrated in FIG. 3C, the gate stack 32 is formed by a different method with a different structure. The gate stack 32 may be formed by various deposition techniques and a proper procedure, such as gate-last process, wherein a dummy gate is first formed, and then is replaced by a metal gate after the formation the source/drain features. Alternatively, the gate stack 32 is formed by a high-k-last a process, wherein both gate dielectric material layer and the gate electrode are replaced by high k dielectric material and metal, respectively, after the formation of the source/drain features. In a high-k-last process, a dummy gate is first formed by deposition and patterning; then source/drain features are formed on sides of gate stack and an inter-layer dielectric layer is formed on the substrate; the dummy gate is removed by etching to result in a gate trench; and then the gate materials (including materials of the gate dielectric layer and the gate electrode) are deposited in the gate trench. In the present example, the gate electrode 44 includes a work function metal layer 44A and a filling metal 44B, such as aluminum or copper. Such formed gate stack 32 has various gate material layers in a U-shape. The compositions of the gate electrode 44 and various conductive features in an interconnect structure (to be described later) are well designed for material integration, fabrication and device performance based on experiment data, simulation and analysis. In the disclosed embodiment, the gate electrode 44 is free of tungsten (W) but includes titanium nitride (TiN), such as for the gate electrode of a p-type FET or titanium aluminum nitride (TiNAl), such as for the gate electrode of an n-type FET.

The IC structure 20 includes various standard cells placed and configured on the semiconductor substrate 12 according to the predefined rules. A standard cell is a group of transistor and interconnect structures that provides a Boolean logic function or a storage function (such as flipflop or latch). Those standard cells are pre-designed and collected in an IC standard cell library for repeatedly use during IC design for compatible, consistent, and efficient IC design and IC fabrication. A filler cell is an IC designed block inserted between two adjacent standard cells to be compatible with IC design and IC fabrication rules. Proper design and configuration of the standard cells and filler cells can enhance the packing density and circuit performance. In the present embodiment illustrated in FIG. 2E, each standard cell includes two dielectric gates configured at the two boundary lines oriented along the Y direction. Each filler cell may include two dielectric gates at the two boundary lines oriented along the X direction. Furthermore, a standard cell and an adjacent filler cell share a dielectric gate at the common boundary.

Referring back to FIGS. 2A through 2D, the IC structure 20 further includes an interconnect structure 46 disposed on the substrate 12 and configured to couple various devices into an integrated circuit. The interconnect structure 46 includes metal lines distributed in multiple metal layers for horizontal routing and vias and contacts to provide vertical connections between adjacent metal layers or between lowest metal layer and the substrate 12 or other device features (such as gate electrodes) formed on the substrate 12. Various conductive features are embedded in an interlayer dielectric (ILD) layer 48, or additionally an etch-stop layer (ESL) disposed underlying the ILD layer 48. The ILD layer 48 includes one or more suitable dielectric material, such as low-k dielectric material, silicon oxide, other suitable dielectric material or a combination thereof. The ILD layer 48 is formed by a suitable procedure, such as deposition and chemical mechanical polishing (CMP).

In the disclosed embodiment, the interconnect structure 46 includes a gate contact 50 disposed on the gate 30 and electrically connected to the gate electrode of the gate 30. The gate contact 50 includes one or more conductive material, such as titanium (Ti), titanium nitride (TiN), tungsten (W) or a combination thereof. In one embodiment, the gate contact 50 includes bulk W with a conformal barrier layer of Ti and TiN surrounding the bulk W. The formation of the gate contact 50 includes patterning the ILD layer 48, depositing the conductive material(s) and CMP. Especially, the gate contact 50 is different from the S/D feature 36 in terms of formation and composition in order to optimize the fabrication capability and processing windows, which will be further described below with the S/D contact.

The interconnect structure 46 includes S/D contacts distributed in in two layers formed respectively, each by a procedure that includes deposition, a lithography patterning, and etching. Particularly, the interconnect structure 46 includes a first S/D contact 52 disposed on the S/D feature 36 and a second S/D contact 54 disposed on the first S/D contact 52. The first S/D feature 52 and the second S/D feature 54 are different in terms of composition and formation. In the disclosed embodiments, the first S/D contact 52 includes tungsten (W) while the second S/D contact 54 includes W or ruthenium. The first S/D contact 52 and second S/D contact 54 are formed respectively by individual procedures, wherein each procedure includes patterning by lithography and etch; deposition and CMP according to some embodiments. Furthermore, the procedure to form the gate contact 50 is separated from the procedure of forming the first S/D feature 52 and the procedure of forming the second S/D feature 54. The contact structures, fabrication procedures and compositions are designed such due to various considerations, manufacturing data and simulation data, as detailed below. When IC technology is progressing to advanced technology nodes with reduced feature sizes, contact sizes and spacing between contact and other adjacent conductive feature are also reduced. Thus, misalignment tolerance is reduced due to reduced spacing, the gap (trench or hole) filling capability during depositions of conductive material(s) is also reduced due to the reduced opening size of the trenches, and the contact conductance is also reduced due to the contact size being reduced beyond the mean free path of the corresponding material. Accordingly, the S/D contact structure is distributed into two layers with more freedoms of different sizes and different compositions so that the first S/D contact 52 is designed with a less size and with conductive material(s) for high gap filling efficiency and the second S/D contact 54 is designed with a greater size and with conductive material(s) for gap filling efficiency and conductance. For example, the second S/D contact 54 is deigned with a composition, such as W, or Ru. In furtherance of the example, Ru has relatively higher conductivity when the contact size is reduced beyond a certain dimension, and Ru can be used with better integration with the ILD layer. Accordingly, the barrier layer can be eliminated without interdiffusion issues, and therefore, bulk Ru size is relatively enlarged. For the gate contact 50, when is formed separately, the misalignment issue can be reduced through the enhanced patterning resolution due to the multiple patterning technologies, such as self-aligned processes including selective deposition, self-aligned etch or a combination thereof. Additionally, the gate contact 50 can be designed with more freedom for respective size and composition. For example, the gate contact 50 may use W or may additionally include Ti/TiN as a barrier layer while the gate electrode is free of W to achieve etch selectivity and reduce the gate damage during the formation of the gate stack 50.

The gate contact 50, the first S/D contact 52, and the second S/D contact 54 may be formed in any proper sequence for optimized fabrication performance. In some embodiments, the first S/D contact 52 is first formed by a damascene process that includes patterning the ILD layer 48 to form a contact hole (or contact trench); filling the corresponding conductive material by deposition; and CMP. The second S/D contact 54 is formed thereafter by the procedure similar to the procedure to form the first S/D contact 52. Thereafter, the gate contact 5o is formed by the procedure similar to the procedure to form the first S/D contact 52.

The additional designs standard cells are further applied to the contacts including the locations, sizes, shapes or a combination thereof, which are described below in detail. The first S/D contact 52 and the second S/D contact 54 have different shapes and configurations, such as illustrated in FIG. 2A. In the disclosed embodiment, as illustrated in FIG. 2A, the first S/D contact 52 has an elongated shape longitudinally oriented along the Y direction and extends onto and electrically connected to the adjacent active regions 22 while the second S/D contact 54 has a square shape landing on the first S/D contact 52. In furtherance of the embodiment, the second S/D contact 54 spans a dimension less than a dimension of the first S/D contact 52 along the same direction (X direction) such that the second S/D contact 54 is completely landing on the first S/D contact 52. In some embodiments, the first S/D contact 52 extends over multiple active regions from the n-well 26 to the p-well 28 while the corresponding second S/D contact 54 is landing on the first S/D contact 52 and may be configured within the n-well 26 or the p-well 28.

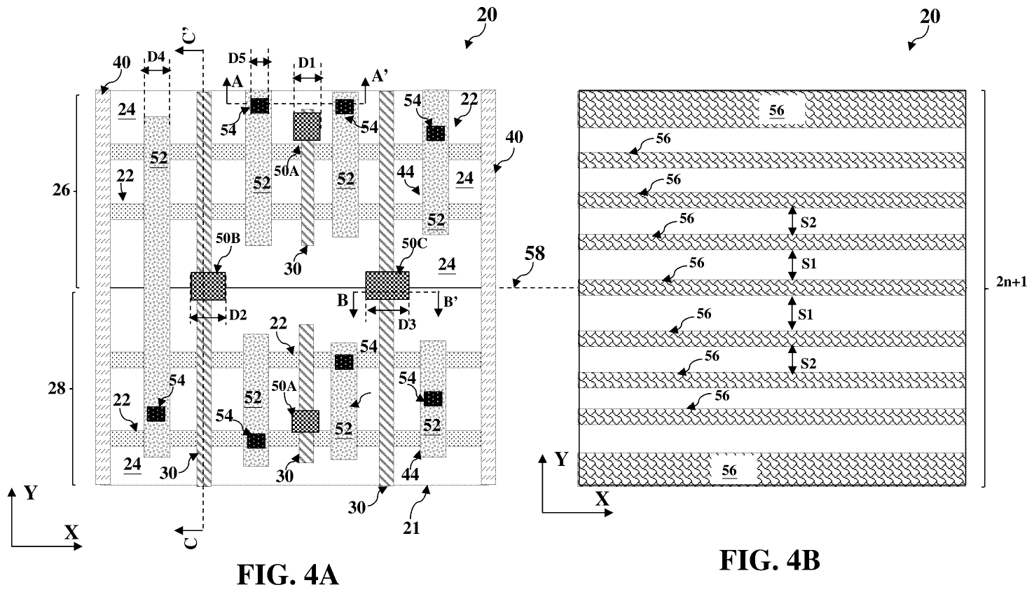

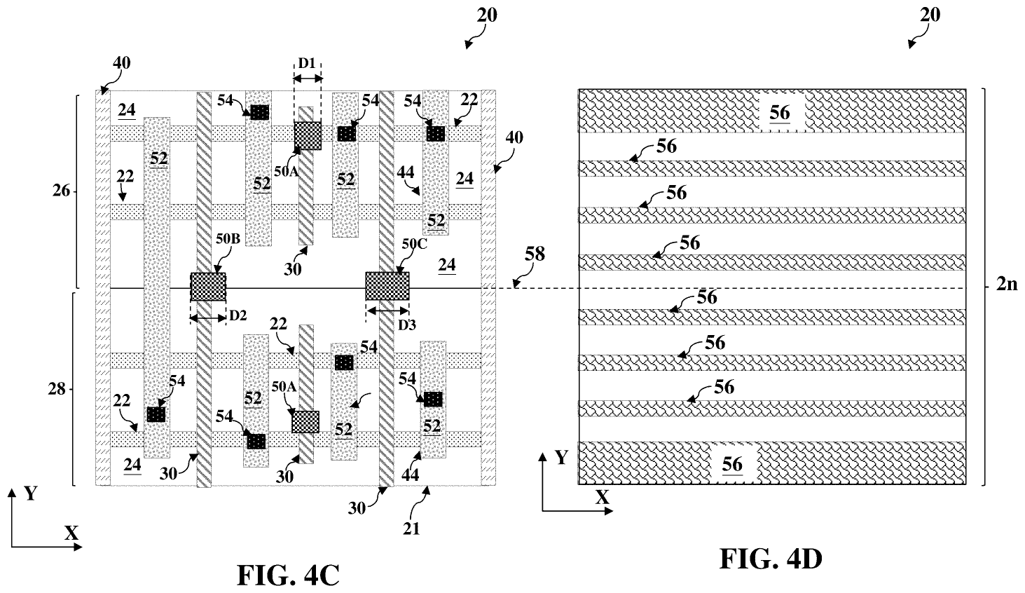

FIGS. 4A through 4D are top views of a standard IC cell 20 constructed in accordance with various embodiments. In the disclosed embodiment, the standard IC cell 20 includes a number of active regions, such as 2 to 10 active regions. The IC standard cell 20 elongated active regions 22 longitudinally oriented along X direction and gates 30 longitudinally oriented along Y direction. In the disclosed embodiment, the standard IC cell 20 includes dielectric gates 40 positioned on the cell boundary lines. In some embodiments, the dielectric gates 40 positioned on the cell boundary lines may be replaced by metal gates 30, depending on individually application and design consideration. The active regions 22 may be planar active regions, or fin active regions or active regions with multiple channels vertically stacked, such as gate-all-around (GAA) structure.

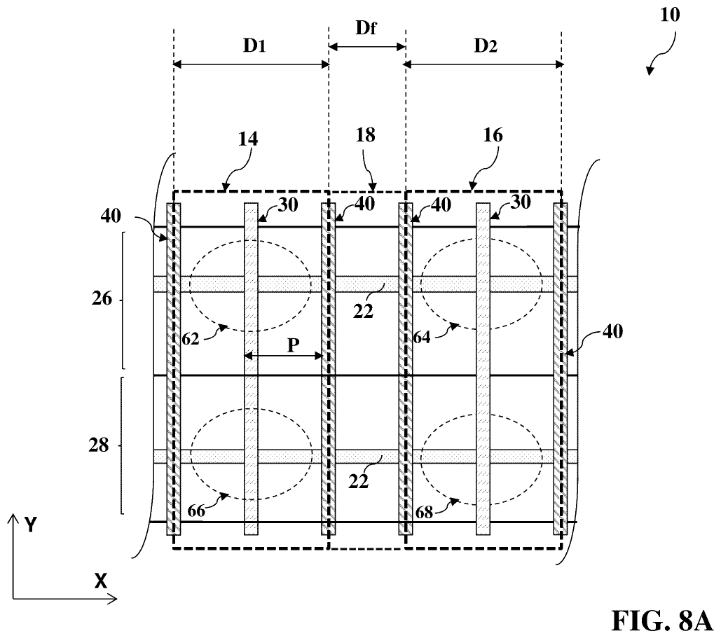

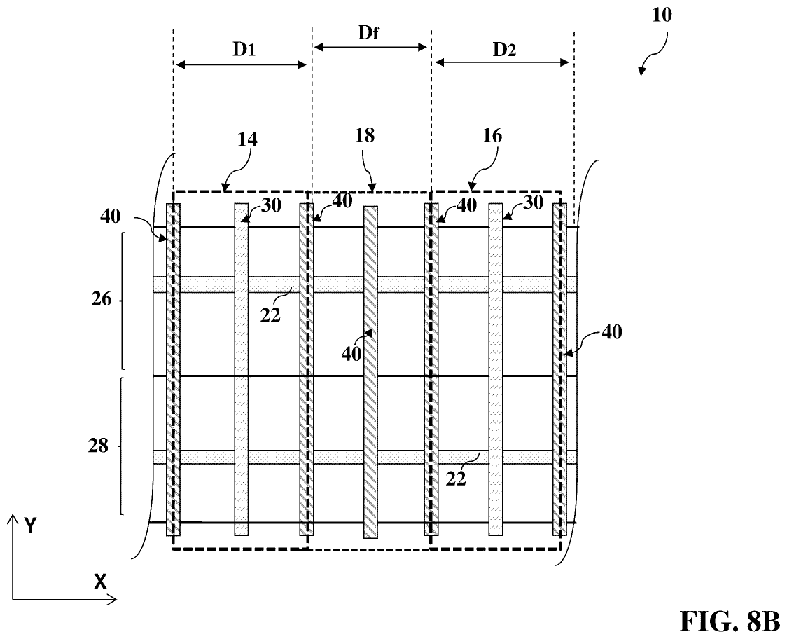

As to the gate contact 50, the configurations are classified into three categories/types, which is further described in detail with reference to FIGS. 4A through 4D. The three types of the gate contacts 50 are configured in different environments. The first type of the gate contacts is referred by 50A, in which a gate contact 50A is configured in a location both sides along X direction are next to S/D contact(s), as illustrated in FIG. 4A. The second type of the gate contacts is referred by 50B, in which a gate contact 50B is configured in a location one side along X direction is next to S/D contact(s), as illustrated in FIG. 4A. The third type of the gate contacts is referred by 50C, in which a gate contact 50C is configured in a location both sides along X direction are free from or far away from S/D contact(s), as illustrated in FIG. 4A. A S/D contact is next to a gate contact is referred to as being adjacent. Usually, the gate 30 are configured evenly with a gate pitch P, which is defined as a dimension from gate edge to same edge of an adjacent gate, as illustrated in FIG. 8A. Here, a S/D contact is adjacent a gate contact is defined a spacing therebetween is P/2 or less. If no S/D contact is adjacent a gate contact, the gate contact is referred to as being free from any S/D contact.

Three types of gate contacts are configured in different environments and therefore have different freedom and different levels of concerns, and accordingly are designed with different sizes and shapes. The considerations in the design include trade off between greater size (leading to reduced contact resistance) and less size (leading to less short issue and greater processing window).

The first type of the gate contacts 50A, due to more constrains from the environment, is designed with a less size D1 to avoid short issue. The second type of the gate contacts 50B is configured with an intermediate size D2 to avoid less stringent short issue since only one side is constrained. D2 is greater than D1. In the disclosed embodiment, the ratio D2/D1 ranges between 1.2 and 1.5. In some embodiments, the first type gate contacts 50A is shaped as square and the second type gate contact 5BA is shaped as rectangle (also referred to as slot contact). Furthermore, the second type gate contacts 50B may be positioned asymmetrically such that the center is shifted away from the side having S/D contact(s) and toward the side free of any S/D contact.

The third type gate contact 50C, due to open space without constrains from both sides, is designed with a greater size D3 to increase the contact area and reduce contact resistance. In the disclosed embodiment, the ratio D3/D2 equals the ratio D2/D1. In furtherance of embodiment, the ratio D3/D2 ranges between 1.2 and 1.5. In some embodiments, the third type gate contact 50C is shaped as rectangle since it has freedom to extend to both sides. Furthermore, the second type gate contacts 50C may be positioned symmetrically such that the center is aligned with the center of the gate 30 along X direction. Especially, the third gate contact 50C extends beyond the edges of the gate 30 with a margin greater than 20% on each side.

The S/D contacts 52 and 54 are also designed with proper dimensions to optimize the processing windows and the contact areas. The first S/D contact 52 spans a dimension D4 along X direction and the second S/D contact 54 spans a dimension D5 along X direction, wherein D4 and D5 are different. Particularly, D4 is greater than D5 according to some embodiments. In furtherance of the embodiments, a ratio D4/D5 ranges between 1.2 and 1.4. In some embodiments, a ratio D4/D1 ranges between 0.8 and 1.2.

The interconnect structure 46 includes metal lines distributed in multiple metal layers and vias configured between adjacent metal layers for vertical connection. First metal lines 56 in the first metal layer (lowest metal layer), as illustrated in FIG. 4B, are electrically connected to various device components, such as S/D features 36 and gate electrodes 42 through respective contacts, such as first S/D contacts 52, the second S/D contacts 54 and the gate contacts 50. In some embodiments, the first metal lines 56 disposed on the standard cell 20 include an odd number (2n+1) of the first metal lines longitudinally oriented along X direction. In that case, 2n first metal lines are symmetrically distributed on the n-well 26 and the p-well 28 with one first metal line 56 positioned on the common edge 58 of the n-well 26 and the p-well 28 as illustrated in FIGS. 4A and 4B.

In some alternative embodiments, the first metal lines 56 are unevenly distributed to make more space for the gate contacts 50. In some embodiments illustrated in FIG. 4B, the central one of the first metal lines 56 is distanced with adjacent first metal lines with a spacing S1 and other first metal lines 56 in the standard IC cell 20 are distanced with a spacing S2 less than S1. Thus, the gate contact 50C and the central one of the first metal line 56 have increased alignment margin and enhanced processing window. In some embodiments, a ratio S1/S2 ranges between 1.2 and 1.4.

In some embodiments, the first metal lines 56 disposed on the standard cell 20 include an even number (2n) of the first metal lines longitudinally oriented along X direction. In that case, 2n first metal lines are symmetrically distributed on the n-well 26 and the p-well 28 while the common edge 58 of the n-well 26 and the p-well 28 falls in a gap between adjacent first metal lines 56 as illustrated in FIGS. 4C and 4D.

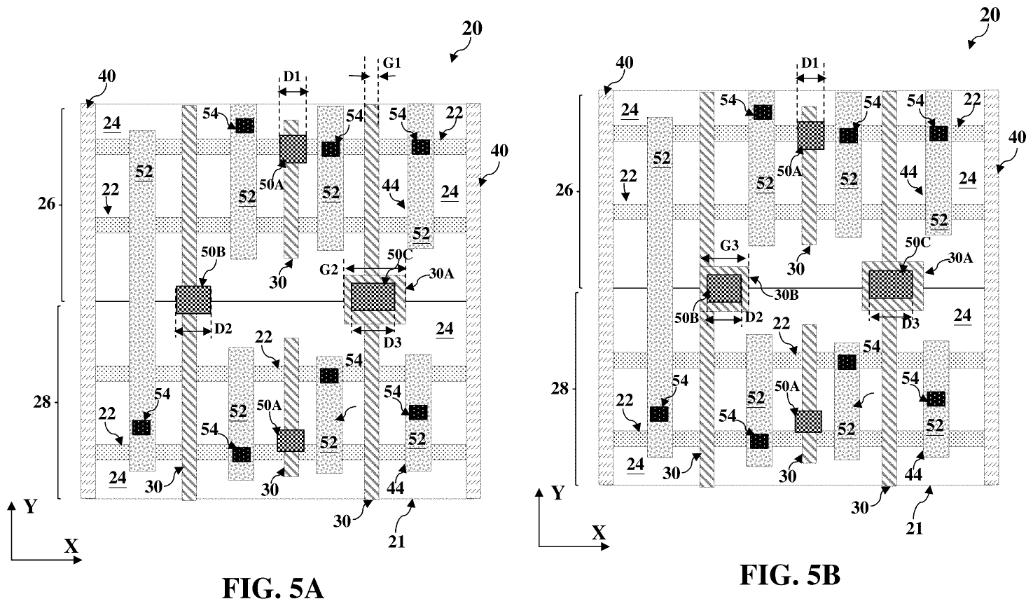

In some alternative embodiments, the gates 30 also utilize respective freedom to reshape and resize for increased alignment window and increased contact area (the increased contact conductance as well). As illustrated in FIG. 5A, the gate 30 associated with the gate contact 50C includes a segment 30A having an increased size along X direction so that the gate contact 50C is able to be landing on the reshaped and resized segment 30A with increased contact area and enhanced alignment/fabrication margin. The gate 30 spans a dimension G1 along X direction while the reshaped segment 30A spans a dimension G2 along X direction. In the disclosed embodiment, a ratio G2/G1 ranges between 2 and 3. In other embodiments, a ratio G2/D3 ranges between 1.5 and 2. In some embodiments, the ratio of the corresponding dimensions of the segment 30A and the gate contact 50C along Y direction have a similar range, such as ranging between 1.2 and 1.5.

In some alternative embodiments, as illustrated in FIG. 5B, the gate 30 associated with the gate contact 50B includes a segment 30B having an increased size along X direction so that the gate contact 50B is able to be landing on the reshaped and resized segment 30B with increased contact area and enhanced alignment/fabrication margin. The reshaped segment 30B spans a dimension G3 along X direction. In the disclosed embodiment, a ratio G3/G1 ranges between 1.3 and 2. In other embodiments, a ratio G3/D2 ranges between 1.2 and 1.5. Particularly, the reshaped segment 30B is shifted toward the free side such that it is substantially extruded toward the free side while the edge on the other side is substantially aligned with the edge of the rest of the gate 30, as illustrated in FIG. 5B. In some embodiments, the ratio of the corresponding dimensions of the segment 30B and the gate contact 50B along Y direction have a similar range, such as ranging between 1.2 and 1.5.

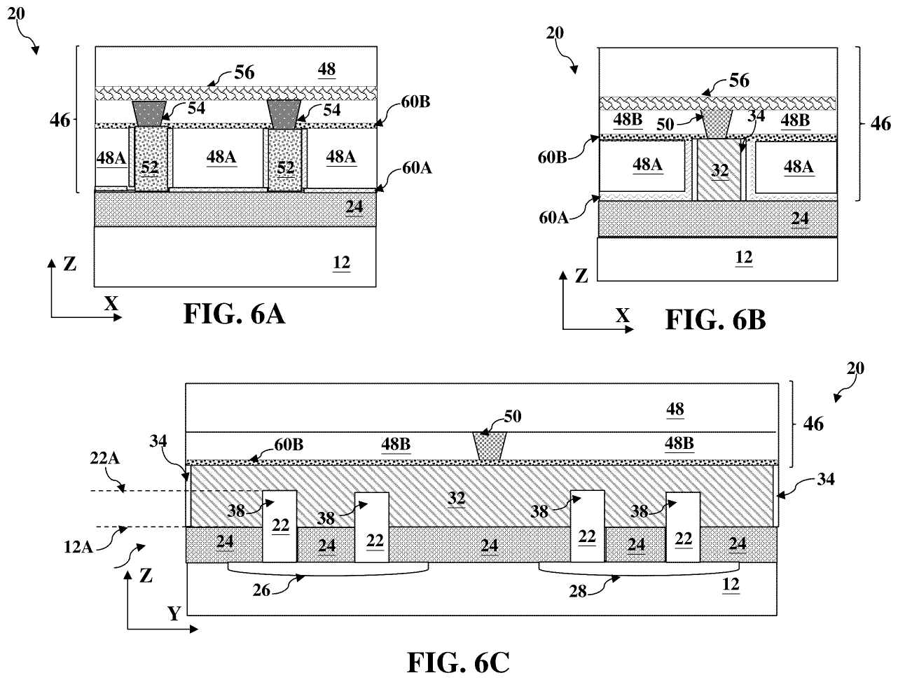

The standard IC cell 20 is further described with FIGS. 6A through 6C. FIGS. 6A through 6C are sectional views of the standard IC cell 20 along dashed lines AA′, BB′ and CC′ of FIG. 4A, respectively, constructed in accordance with some embodiments. As described above, various contacts are formed separately. The ILD structure includes multiple layers, each layer is patterned to form respective contacts. Furthermore, an etch stop layer 60 is additionally disposed underlying the corresponding ILD layer 48 to achieve the etch selectivity. In this case, the etch stop layer 60 and ILD layer 48 have different compositions with etch selectivity. Especially, the first S/D contacts 52 and the second S/D contacts 54 are formed in different ILD layers 48 and corresponding etch stop layers 60.

The first S/D features 52 are formed as described below. As illustrated in FIG. 6A, a first etch stop layer 60A is deposited conformally, and a first ILD layer 48A is deposited on the first etch stop layer 60A. In some embodiments, the first etch stop layer 60A includes silicon nitride or silicon oxynitride while the first ILD layer 48A includes silicon oxide, a low-k dielectric material or a combination thereof. A CMP process is applied to planarize the top surface. Then the ILD layer 48A and the etch stop layer 60A are patterned to form contact holes for the first S/D contacts 52 by an etch procedure. The etch procedure includes a first etch process, such as a wet etch or a dry etch, with an etchant to selectively etch the first ILD layer 48A and stops on the etch stop layer 60A, Then, a second etch process, such as a wet etch with an etchant to selectively etch the etch stop layer 60A. Thus, the etch procedure can avoid over etch to the ILD layer 48A and damage the substrate or device features, such as S/D features 36. Conductive material(s) is deposited in the contact holes and another CMP process is applied to planarize the top surface, thereby forming the first S/D features 52.

The second S/D features 54 are formed similarly but in a second ILD layer 48B and a second etch stop layer 60B. As illustrated in FIG. 6A, a second etch stop layer 60B is deposited conformally, and a second ILD layer 48B is deposited on the second etch stop layer 60B. In some embodiments, the second etch stop layer 60B includes silicon nitride or silicon oxynitride while the second ILD layer 48B includes silicon oxide, a low-k dielectric material or a combination thereof. A CMP process is applied to planarize the top surface. Then the ILD layer 48B and the etch stop layer 60B are patterned to form contact holes for the second S/D contacts 54 by an etch procedure. The etch procedure includes a first etch process, such as a wet etch or a dry etch, with an etchant to selectively etch the second ILD layer 48B and stops on the etch stop layer 60B, Then, a second etch process, such as a wet etch with an etchant to selectively etch the etch stop layer 60B. Conductive material(s) is deposited in the contact holes and another CMP process is applied to planarize the top surface, thereby forming the second S/D features 54.

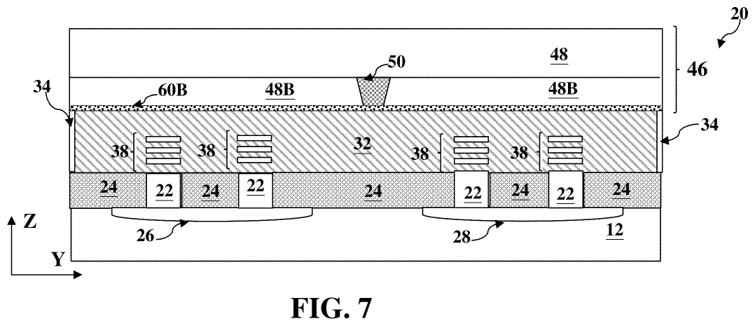

The standard IC cell 20 is further described with FIG. 7 in a sectional view of the standard IC cell 20 along dashed line CC′ of FIG. 4A, constructed in accordance with some embodiments. FIG. 7 is similar to FIG. 6C. However, the channel structure is different. Each active region 22 includes multiple channels 38 vertically stacked, the gate 30 wraps around the channels. This structure is also referred to as gate-all-around (GAA) structure. In some embodiments, the number of channels 38 stacked on may vary, such as 3 to 10. In some embodiments, the number of channels 38 in n-well 26 is different from the number of channels 38 in p-well 28.

FIGS. 8A and 8B are top views of the IC structure 10 constructed in accordance with some embodiments. FIGS. 8A and 8B illustrated two adjacent standard IC cells 14 and 16, which are similar to those described above, such as the standard IC cell 20 in FIGS. 2A through 7. The fill cell 18 is further described in detail. In FIG. 8A, only one active region 22 in n-well 26 and one active region in p-well 28 is illustrated. However, it is understood that any proper number of active regions 22, such 2 to 10, is possible, depending on the individual standard IC cell and its corresponding function. Similarly, only one gate 30 in each standard IC cell is illustrated. However, it is understood that any proper number of gates 30, such 1 to 10, is possible, depending on the individual standard IC cell and its corresponding function. The gates 30 are substantially distributed with a pitch P. If a standard IC cell includes one gate, the dimension of the cell along X direction is 2P. If the standard IC cell includes N gate, the dimension of the cell along X direction is (N+1)P. The fill cell 18 includes two dielectric gates and spans a dimension Df=P while D1=N₁P and D2=N₂Pi, in which the first cell 14 includes N₁ gates 30 and the second cell 16 includes N₂ gates 30. Furthermore, the active regions 22 continuously extend from the first cell 14 to the second cell 16. Various FETs, such as p-type FETs (pFETs) 62, 64, and n-type FETs (nFETs) 66, 68, are formed in the IC structure 10.

When the second standard cell 16 is placed next to the first standard cell 14, it is configured with a fill cell 18 interposed between, and the fill cell 18 spans a dimension De of one pitch dimension P.

Each standard cell (such as 14 and 16) is bordered by a dielectric gate 40 as illustrated in FIG. 8A. For example, the first standard cell 14 spans a first dimension D₁ along the X direction and the second standard cell 16 spans a second dimension D2 along the X direction. In the present design, D₁>D_{f} and D₂>D_{f}.

Each standard cell includes at least one gate 30 configured to form one or more field effect transistor. In the present embodiment, the first standard cell 14 and the second standard cell 16 each includes at least one gate 30. The gates 30 and the dielectric gates 40 are equally distanced. In other words, all gates (including dielectric gates 30 and gates 40) are configured into a periodic structure with a pitch P. Here the pitch is the dimension measured from the same location of the adjacent features, such as center to center. Thus, the fill cell 18 spans one pitch dimension D_{f}=P, along the Y direction. The first standard cell 14 spans a two-pitch dimension or D₁=2*P along the X direction. Similarly, the second standard cell 16 spans a two-pitch dimension or D₂=2*P, along the X direction.

Especially, each active region 22 has a continuous structure extending through the adjacent standard cells (such as 14 and 16) and the fill cell 18 is interposed therebetween. According to the present disclosure, when the second standard cell is placed next to the first standard cell, the second standard cell is separated from the first standard cell by a fill cell 18 having a one pitch dimension P; and all gates 30 and dielectric gates 40 are placed over the same continuous active region (s) 22.

In the present embodiment, the IC structure 10 includes the first active region 22 in the N well 26 and the second active region 22 in the P well 28. The gate 30 in the first standard cell 14 extends continuously from the first active region 22 (in the N well 26) to the second active region 22 (in the P well 28) along the Y direction. Similarly, the gate 30 in the second standard cell 16 extends continuously from the first active region 22 (in the N well 26) to the second active region 22 (in the P well 28) along the Y direction. The dielectric gates 40 on the boundary lines of the standard cells also extends continuously from the first active region 22 (in the N well 26) to the second active region 22 (in the P well 28) along the X direction. Each gate 30 is next to a dielectric gate 40. Since the active regions are continuous, the isolation between transistors is achieved by the dielectric gates 40.

With S/D features 36 and channel(s) 38 formed for each transistor associated with a respective active region and a respective standard cell, the first standard cell 14 includes one p-type FET (pFET) 62 in the N well 26 and one n-type FET (nFET) 66 in the P well 28; and the second standard cell 16 includes one pFET 64 in the N well 26 and one nFET 68 in the P well 28. In the present embodiment, the pFET 62 and the nFET 66 in the first standard cell 14 are integrated to form a functional circuit block, such as a complimentary FET; and the pFET 64 and the nFET 68 in the second standard cell 16 are integrated to form a functional circuit block, such as another complimentary FET.

Thus, the adjacent standard cells have a spacing of one pitch dimension P, which ensure logic circuit packing density. The active regions are continuous through multiple cells, and a transistor is isolated by the dielectric gate 40. The continuity of the active regions maintains a regular layout for fabrication friendliness. In some embodiments, since a transistor is always next to a dielectric gate, the design uncertainty is reduced. There is not abutment constrain during cell placement with continuous active region and isolation by dielectric gate. Furthermore, the uniform local density of the dielectric gates 40 and the gates 30 lead to better device performance and processing uniformity.

When placing a standard cell next to another standard cell, the above defined rules applied. Generally, multiple standard cells may be thus placed in a cascade mode. In this case, the filler cell interposed between two adjacent standard cells spans between the two standard cells one pitch dimension. The first standard cell adjoins the filler cell from one side on a dielectric gate and the second standard cell adjoins the filler cell from another side on another dielectric gate.

In FIG. 8B, the fill cell 18 include three dielectric gates 40 evenly distributed and spans a dimension Df=2P along X direction while D1=N₁P and D2=N₂P.

The present disclosure provides various embodiments of an IC structure having multiple standard cells configured according to the predefined rules. In various embodiments described above, standard cells include S/D contacts and gate contacts, respectively formed with different compositions. Particularly, the gate contacts are classified into three categories each having a different environment and the gate contacts in different environments are designed with different shapes and different sizes for optimize contact areas and alignment margins. The gates are further reshaped according to the respective environment to enhance the contact area and the processing window. The S/D contacts includes two layers formed separately and include different compositions for optimized fabrication capability and circuit performance. Various advantages may present in various embodiments. By utilizing the disclosed layout having multiple standard cells, the IC structure, such as a logic circuit, has a high packing density, enhanced circuit performance, and collectively enhanced power-performance-area-cost (PPAC).

In one example aspect, the present disclosure provides an integrated circuit (IC) structure. The IC structure includes a first standard cell having a first p-type field-effect transistor (pFET) and a first n-type field-effect transistor (nFET) integrated; a first, second and third gates longitudinally oriented along a first direction and configured in the first standard cell; a first gate contact landing on the first gate and being adjacent two source/drain (S/D) contacts on two opposite edges of the first gate; a second gate contact landing on the second gate and being adjacent a single S/D contact on one edge of the second gate; and a third gate contact landing on the third gate and being free from any S/D contact. The first gate contact spans a first dimension D1 along a second direction being orthogonal to the first direction, the second gate contact spans a second dimension D2 along the second direction, the third gate contact spans a third dimension D3 along the second direction, and D1 is less than D2 and D2 is less than D3.

Another one aspect of the present disclosure pertains to an IC structure. The IC structure includes a first standard cell having a first p-type field-effect transistor (pFET) and a first n-type field-effect transistor (nFET) integrated, and having a first dielectric gate on a first standard cell boundary; a second standard cell being adjacent to the first standard cell, having a second pFET and a second nFET integrated, and having a second dielectric gate on a second standard cell boundary; and a first fill cell configured between the first and second standard cells, and spanning between the first dielectric gate and the second dielectric gate. The first standard cell further includes a first and second gates longitudinally oriented along a first direction and configured in the first standard cell; a first gate contact landing on the first gate and being adjacent two source/drain (S/D) contacts on two opposite edges of the first gate; and a second gate contact landing on the second gate and being adjacent a single S/D contact on one edge of the second gate. The first gate contact spans a first dimension D1 along a second direction being orthogonal to the first direction, the second gate contact spans a second dimension D2 along the second direction, and D1 is less than D2.

Yet another aspect of the present disclosure pertains to a method making an integrated circuit. The method includes forming a first and second active regions on a semiconductor substrate and longitudinally oriented along a first direction, the first and second active regions are separated by an isolation feature; forming a first and second gate electrodes longitudinally extending over the first and second active regions along a second direction that is perpendicular to the first direction; forming a source/drain contact landing on the first and second active regions; and forming a first and second gate contacts landing on the first and second gate electrodes, respectively. The source/drain contact is spaced a first distance to the first gate contact and a second distance to the second gate contact, the first distance being greater than the second distance. The first gate contact is extending from the first gate electrode to the isolation feature and is spanning a first width along the first direction. The second gate contact is spanning a second width along the first direction, the second width being less than the first width.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. An integrated circuit, comprising:
a first standard cell having a first p-type field-effect transistor (pFET) and a first n-type field-effect transistor (nFET) integrated;
a first, second and third gates longitudinally oriented along a first direction and configured in the first standard cell;
a first gate contact landing on the first gate and being adjacent two source/drain (S/D) contacts on two opposite edges of the first gate;
a second gate contact landing on the second gate and being adjacent a single S/D contact on one edge of the second gate; and
a third gate contact landing on the third gate and being free from any S/D contact, wherein
the first gate contact spans a first dimension D1 along a second direction being orthogonal to the first direction,
the second gate contact spans a second dimension D2 along the second direction,
the third gate contact spans a third dimension D3 along the second direction, and
D1 is less than D2 and D2 is less than D3.

2. The integrated circuit of claim 1, wherein a first ratio D2/D1 is equal to a second ratio D3/D2.

3. The integrated circuit of claim 2, wherein each of the first ratio D2/D1 and the second ratio D3/D2 ranges between 1.2 and 1.5.

4. The integrated circuit of claim 1, further comprising
a second standard cell being adjacent to the first standard cell, having a second pFET and a second nFET integrated; and
a first dielectric gate disposed between the first and second standard cells.

5. The integrated circuit of claim 4, further comprising
a second dielectric gate disposed between the first and second standard cells; and
a first fill cell configured between the first and second standard cells and spanning between the first dielectric gate and the second dielectric gate, wherein the first dielectric gate is disposed on a boundary of the first standard cell, and the second dielectric gate is disposed on a boundary of the second standard cell.

6. The integrated circuit of claim 5, wherein the first fill cell further includes a third dielectric gate interposed between the first and second dielectric gates.

7. The integrated circuit of claim 5, wherein
the first pFET and the second pFET are formed on a first continuous active region;
the first nFET and the second nFET are formed on a second continuous active region;
the first and second continuous active regions longitudinally oriented along the second direction; and
the first and second dielectric gates longitudinally oriented along the first direction and extending from the first continuous active region to the second continuous active region.

8. The integrated circuit of claim 7, wherein
the first gate spans a first dimension G1 along the second direction;
the second gate includes a first segment overlapped with the second gate contact, the first segment spanning an increased dimension G2 along the second direction; and
G2 is greater than G1.

9. The integrated circuit of claim 8, wherein
the third gate includes a second segment overlapped with the third gate contact, the second segment spanning an increased dimension G3 along the second direction; and
G3 is greater than G2.

10. The integrated circuit of claim 9, wherein
a ratio G2/G1 ranges between 1.5 and 2; and
a ratio G3/G1 ranges between 2 and 3.

11. An integrated circuit, comprising:
a first standard cell having a first p-type field-effect transistor (pFET) and a first n-type field-effect transistor (nFET) integrated, and having a first dielectric gate on a first standard cell boundary;
a second standard cell being adjacent to the first standard cell, having a second pFET and a second nFET integrated, and having a second dielectric gate on a second standard cell boundary; and
a first fill cell configured between the first and second standard cells, and spanning between the first dielectric gate and the second dielectric gate, wherein the first standard cell further includes
a first and second gates longitudinally oriented along a first direction and configured in the first standard cell;
a first gate contact landing on the first gate and being adjacent two source/drain (S/D) contacts on two opposite edges of the first gate; and
a second gate contact landing on the second gate and being adjacent a single S/D contact on one edge of the second gate, wherein
the first gate contact spans a first dimension D1 along a second direction being orthogonal to the first direction,
the second gate contact spans a second dimension D2 along the second direction, and
D1 is less than D2.

12. The integrated circuit if claim 11, wherein
the first pFET and the second pFET are formed on a first continuous active region, and
the first nFET and the second nFET are formed on a second continuous active region.

13. The integrated circuit if claim 12, wherein
each of the first and second continuous active regions includes multiple channels vertically stacked; and
each of the first and second gates wraps around the multiple channels.

14. The integrated circuit if claim 12, further comprising:
a third gate longitudinally oriented along the first direction and configured in the first standard cell; and
a third gate contact landing on the third gate and being free from any S/D contact, wherein the third gate contact spans a third dimension D3 along the second direction, and wherein D3 is greater than D2.

15. The integrated circuit of claim 14, wherein a first ratio D2/D1 is equal to a second ratio D3/D2, range between 1.2 and 1.5.

16. The integrated circuit of claim 14, wherein
the first gate spans a first dimension G1 along the second direction;
the second gate includes a first segment overlapped with the second gate contact, the first segment spanning an increased dimension G2 along the second direction; and
the third gate includes a second segment overlapped with the third gate contact, the second segment spanning an increased dimension G3 along the second direction; and
G2 is greater than G1, and G3 is greater than G2.

17. The integrated circuit of claim 16, wherein
a ratio G2/G1 ranges between 1.5 and 2; and
a ratio G3/G1 ranges between 2 and 3.

18. A method, comprising:
forming a first and second active regions on a semiconductor substrate and longitudinally oriented along a first direction, the first and second active regions are separated by an isolation feature;
forming a first and second gate electrodes longitudinally extending over the first and second active regions along a second direction that is perpendicular to the first direction;
forming a source/drain contact landing on the first and second active regions; and
forming a first and second gate contacts landing on the first and second gate electrodes, respectively, wherein
the source/drain contact is spaced a first distance to the first gate contact and a second distance to the second gate contact, the first distance being greater than the second distance,
the first gate contact is extending from the first gate electrode to the isolation feature and is spanning a first width along the first direction, and
the second gate contact is spanning a second width along the first direction, the second width being less than the first width.

19. The method of claim 18, further comprising
forming a second source/drain contact landing on the first source/drain contact and directly overlying the isolation feature;
forming a first etch stop layer disposed directly on sidewalls of the first source/drain feature and a top surface of the isolation feature; and
forming a second etch stop layer that directly contacts a top surface of the first source/drain contact, the first etch stop layer and sidewalls of the second source/drain feature.

20. The method of claim 19, wherein
the forming of the first gate contact includes forming the first gate contact positioned symmetrically such that a center of the first gate contact is aligned with a center of the first gate electrode along the first direction;
the forming of the second gate contact includes forming the second gate contact positioned asymmetrically such that a center of the second gate contact is shifted away from a center of the second gate electrode the first direction; and
the first and second gate electrodes are disposed underlying the second etch stop layer.
